(19) United States
(12) Patent Application Publication
(10) Pub. No.: US 2026/0165153 A1
(43) Pub. Date: Jun. 11, 2026

(54) CHIP PACKAGE STRUCTURE

(71) Applicant: inergy Technology Inc., Hsinchu County (TW)

(72) Inventors: Li-Zheng LIN, Hsinchu County (TW); Nan-Wei WEN, Hsinchu County (TW)

(21) Appl. No.: 19/260,287

(22) Filed: Jul. 4, 2025

(30) Foreign Application Priority Data
Dec. 5, 2024 (TW) 113213437

(51) Int. Cl. H01L 23/495; H01L 23/00

(52) U.S. Cl. CPC H10W 70/421; H10W 90/766

(57) ABSTRACT

A chip package structure includes a conductive part, a chip, a copper clip, and a packaging material. The conductive part includes a first source connecting part, a first gate connecting part, a second source connecting part, a second gate connecting part, and a drain connecting part. The first gate connecting part is separated from the first source connecting part. The second source connecting part is located at a side of the first source connecting part. The second gate connecting part is separated from the second source connecting part. The drain connecting part is adjacent to the first source connecting part. The chip is disposed on the conductive part. The chip includes a bottom plate and a top plate. The bottom plate contacts the conductive part. The top plate is connected to the bottom plate. The copper clip is connected to the top plate of the chip.

### CROSS - REFERENCE TO RELATED APPLICATION

This application claims priority to Taiwan Application Serial Number 113213437, filed December 5, 2024, which is herein incorporated by reference in its entirety.

### BACKGROUND

### Field of Invention

The present disclosure relates to a chip package structure.

### Description of Related Art

In general, traditional chip scale packaging (CSP) has the advantages of a thinner structural thickness, good heat dissipation performance, and the capability of being mounted directly using surface mount technology (SMT), such as by soldering with solder balls. However, when it is found to be defective after a component mounted onto a plate, it cannot be replaced manually. In addition, since the component dimensions in traditional chip scale packaging structures are extremely precise, manual mounting of components tends to result in misalignment issues.

Therefore, how to propose a chip package structure that can solve the aforementioned problems is one of the problems that the industry is currently eager to invest in research and development resources to solve.

### SUMMARY

In view of this, one purpose of the present disclosure is to provide a chip package structure that can solve the aforementioned problems.

In order to achieve the above objective, in accordance with an embodiment of the present disclosure, a chip package structure includes a conductive part, a chip, a copper clip, and a packaging material. The conductive part includes a first source connecting part, a first gate connecting part, a second source connecting part, a second gate connecting part, and a drain connecting part. The first gate connecting part is separated from the first source connecting part. The second source connecting part is located on a side of the first source connecting part. The second gate connecting part is separated from the second source connecting part. The drain connecting part is adjacent to the first source connecting part. The chip is disposed on the conductive part. The chip includes a bottom plate and a top plate. The bottom plate is in contact with the conductive part. The top plate is connected to the bottom plate. The copper clip is disposed on the chip and is connected to the top plate of the chip. The packaging material covers the conductive part, the chip, and the copper clip. The top plate of the chip is electrically connected to the drain connecting part by the copper clip. The bottom plate of the chip is connected to the first source connecting part, the first gate connecting part, the second source connecting part, and the second gate connecting part.

In one or more embodiments of the present disclosure, the conductive part further includes a source pin, a gate pin, and a drain pin. The source pin is connected to the second source connecting part. The gate pin is connected to the second gate connecting part. The drain pin is connected to the drain connecting part.

In one or more embodiments of the present disclosure, the second source connecting part and the second gate connecting part are located on the side of the first source connecting part. The drain connecting part is located on the other side of the first source connecting part.

In one or more embodiments of the present disclosure, the first gate connecting part is located between the first source connecting part and the drain connecting part.

In one or more embodiments of the present disclosure, the drain connecting part is separated from the second source connecting part by the first source connecting part.

In one or more embodiments of the present disclosure, the bottom plate of the chip includes a first subchip and a second subchip. The first subchip is disposed on a bottom surface of the chip. The first subchip includes a first source electrode and a first gate electrode electrically connected to the first source electrode. The second subchip is disposed on the bottom surface of the chip and is separated from the first subchip. The second subchip includes a second source electrode and a second gate electrode electrically connected to the second source electrode.

In one or more embodiments of the present disclosure, the first source electrode is connected to the first source connecting part. The first gate electrode is connected to the first gate connecting part. The second source electrode is connected to the second source connecting part. The second gate electrode is connected to the second gate connecting part.

In one or more embodiments of the present disclosure, the copper clip includes a horizontal extending portion and a bending portion. The horizontal extending portion is disposed on the chip. The bending portion extends from an end of the horizontal extending portion.

In one or more embodiments of the present disclosure, the horizontal extending portion is connected to the top plate of the chip. The bending portion is connected to the drain connecting part of the conductive part.

In one or more embodiments of the present disclosure, a bottom surface of the horizontal extending portion is connected to a top surface of the chip.

In order to achieve the above objective, in accordance with an embodiment of the present disclosure, a chip package structure includes a conductive part, a chip, and a copper clip. The conductive part includes a first source connecting part, a first gate connecting part, a second source connecting part, a second gate connecting part, and a drain connecting part. The first gate connecting part is separated from the first source connecting part. The second source connecting part is located on a side of the first source connecting part. The second gate connecting part is separated from the second source connecting part. The drain connecting part is adjacent to the first source connecting part. The chip is disposed on the conductive part. The chip includes a bottom plate and a top plate. The bottom plate is in contact with the conductive part. The top plate is connected to the bottom plate. The copper clip is disposed on the chip and is connected to the top plate of the chip and the drain connecting part. The top plate of the chip is electrically connected to the drain connecting part by the copper clip. The bottom plate of the chip is connected to the first source connecting part, the first gate connecting part, the second source connecting part, and the second gate connecting part.

In one or more embodiments of the present disclosure, the conductive part further includes a source pin, a gate pin, and a drain pin. The source pin is connected to the second source connecting part. The gate pin is connected to the second gate connecting part. The drain pin is connected to the drain connecting part.

In one or more embodiments of the present disclosure, the second source connecting part and the second gate connecting part are located on the side of the first source connecting part. The drain connecting part is located on the other side of the first source connecting part.

In one or more embodiments of the present disclosure, the first gate connecting part is located between the first source connecting part and the drain connecting part.

In one or more embodiments of the present disclosure, the drain connecting part is separated from the second source connecting part by the first source connecting part.

In one or more embodiments of the present disclosure, the bottom plate of the chip includes a first subchip and a second subchip. The first subchip is disposed on a bottom surface of the chip. The first subchip includes a first source electrode and a first gate electrode electrically connected to the first source electrode. The second subchip is disposed on the bottom surface of the chip and is separated from the first subchip. The second subchip includes a second source electrode and a second gate electrode electrically connected to the second source electrode.

In one or more embodiments of the present disclosure, the first source electrode is connected to the first source connecting part. The first gate electrode is connected to the first gate connecting part. The second source electrode is connected to the second source connecting part. The second gate electrode is connected to the second gate connecting part.

In one or more embodiments of the present disclosure, the copper clip includes a horizontal extending portion and a bending portion. The horizontal extending portion is disposed on the chip. The bending portion extends from an end of the horizontal extending portion.

In one or more embodiments of the present disclosure, the horizontal extending portion is connected to the top plate of the chip. The bending portion is connected to the drain connecting part of the conductive part.

In one or more embodiments of the present disclosure, a bottom surface of the horizontal extending portion is connected to a top surface of the chip.

In summary, in the chip package structure of the present disclosure, since the source electrodes and gate electrodes disposed on the bottom plate of the chip are respectively in contact with the source connecting parts and gate connecting parts of the conductive part, the manufacturer does not need to devote effort to alignment between the chip and the conductive part, thereby achieving an effect of ease of assembly. In the chip package structure of the present disclosure, since the top plate of the chip is in contact with the copper clip, and the bending portion of the copper clip is connected to the drain connecting part, wire bonding is not additionally required, thereby simplifying the structural design. Accordingly, the chip package structure of the present disclosure can effectively reduce manufacturing complexity and address the issue in traditional chip scale packaging in which defective components cannot be manually replaced.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is an exploded view of a chip package structure in accordance with an embodiment of the present disclosure;

FIG. 2 is a side view of the chip package structure in accordance with an embodiment of the present disclosure;

FIG. 3 is a top view of a conductive part in accordance with an embodiment of the present disclosure;

FIG. 4 is a top view of a chip in accordance with an embodiment of the present disclosure;

FIG. 5 is a bottom view of the chip in accordance with an embodiment of the present disclosure; and

FIG. 6 is a side view of a copper clip in accordance with an embodiment of the present disclosure.

### DETAILED DESCRIPTION

Hereinafter, a plurality of embodiments of the present disclosure will be disclosed in diagrams. For the sake of clarity, many details in practice will be described in the following description. However, it should be understood that these details in practice should not limit the present disclosure. In other words, in some embodiments of present disclosure, these details in practice are unnecessary. In addition, for simplicity of the drawings, some conventionally used structures and elements will be shown in a simple schematic manner in the drawings. The same reference numbers are used in the drawings and the description to refer to the same or like parts.

Hereinafter, the structure, function, and connection relationships of each component included in a chip package structure 100 of this embodiment will be described in detail.

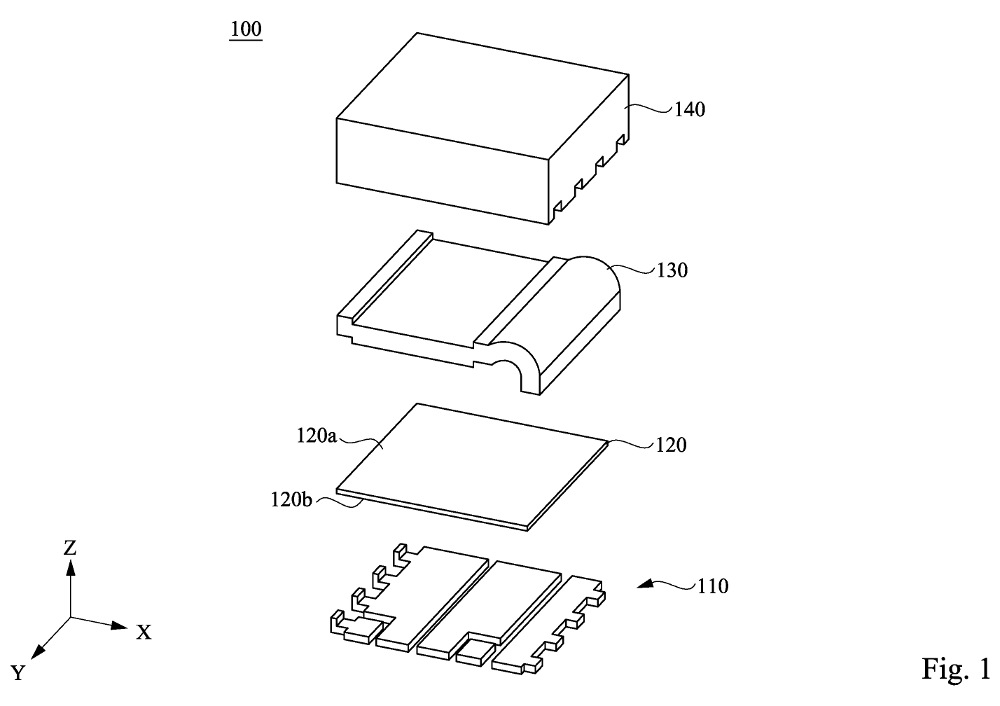

Reference is made to FIG. 1. FIG. 1 is an exploded view of a chip package structure 100 in accordance with an embodiment of the present disclosure. As shown in FIG. 1, in this embodiment, the chip package structure 100 includes a conductive part 110, a chip 120, a copper clip 130, and a packaging material 140. In some embodiments, the conductive part 110, the chip 120, the copper clip 130, and the packaging material 140 are sequentially disposed along a direction. For example, the conductive part 110, the chip 120, the copper clip 130, and the packaging material 140 are sequentially disposed from bottom to top along a Z-direction. As shown in FIG. 1, the chip 120 has a top surface 120a and a bottom surface 120b. In some embodiments, the copper clip 130 is connected to the top surface 120a of the chip 120, and the conductive part 110 is connected to the bottom surface 120b of the chip 120. In some embodiments, the packaging material 140 is configured to cover the conductive part 110, the chip 120, and the copper clip 130.

In some embodiments, the conductive part 110 may be a lead frame.

In some embodiments, the conductive part 110 may be made of a conductive material. In some embodiments, the conductive part 110 may include, for example, copper, a copper alloy, an iron-nickel alloy, or other suitable materials.

In some embodiments, the copper clip 130 may be made of a conductive material. In some embodiments, the copper clip 130 may include, for example, copper or other suitable materials.

In some embodiments, the packaging material 140 may be a solid encapsulating material.

In some embodiments, the packaging material 140 may be an insulating material. In some embodiments, the packaging material 140 may include, for example, epoxy resin, phenolic resin, catalyst, silicon dioxide, or other suitable materials.

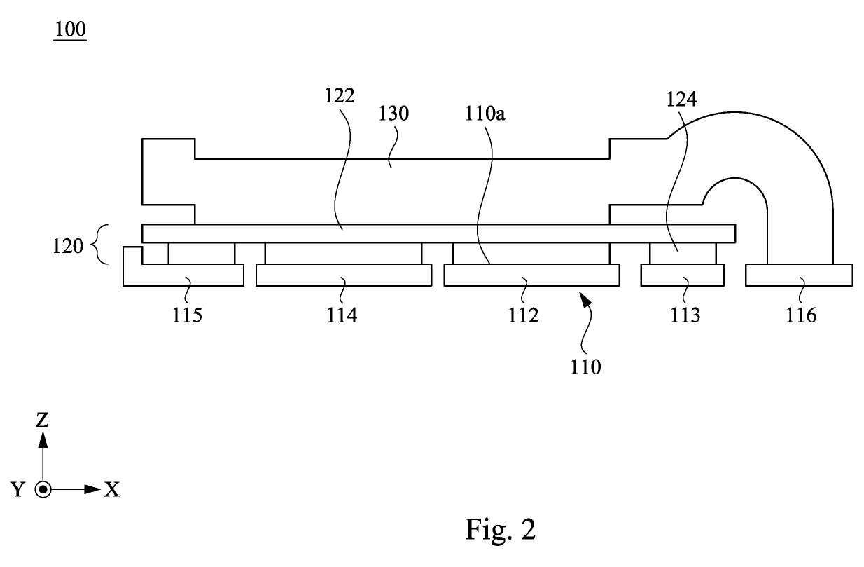

Reference is made to FIG. 2. FIG. 2 is a side view of the chip package structure 100 in accordance with an embodiment of the present disclosure. For simplicity, the packaging material 140 is omitted in FIG. 2. As shown in FIG. 2, in this embodiment, the conductive part 110 includes a first source connecting part 112, a first gate connecting part 113, a second source connecting part 114, a second gate connecting part 115, and a drain connecting part 116. The first source connecting part 112, the first gate connecting part 113, the second source connecting part 114, the second gate connecting part 115, and the drain connecting part 116 are separated from each other. The chip 120 is disposed on the conductive part 110. The chip 120 includes a top plate 122 and a bottom plate 124. The bottom plate 124 is in contact with the conductive part 110. The top plate 122 is connected to the bottom plate 124. It should be noted that, as shown in FIG. 1 and FIG. 2, the top surface 120a of the chip 120 corresponds to the surface of the top plate 122, and the bottom surface 120b of the chip 120 corresponds to the surface of the bottom plate 124. The copper clip 130 is disposed on the chip 120. Specifically, the copper clip 130 is connected to the top plate 122 of the chip 120. As shown in FIG. 2, in some embodiments, one end of the copper clip 130 is connected to the chip 120, and the other end of the copper clip 130 is connected to the conductive part 110. More specifically, one end of the copper clip 130 is connected to the top plate 122 of the chip 120, and the other end is connected to the drain connecting part 116 of the conductive part 110. As shown in FIG. 2, in this embodiment, the chip 120 is electrically connected to the drain connecting part 116 by the copper clip 130, and the bottom plate 124 of the chip 120 is connected to the first source connecting part 112, the first gate connecting part 113, the second source connecting part 114, and the second gate connecting part 115.

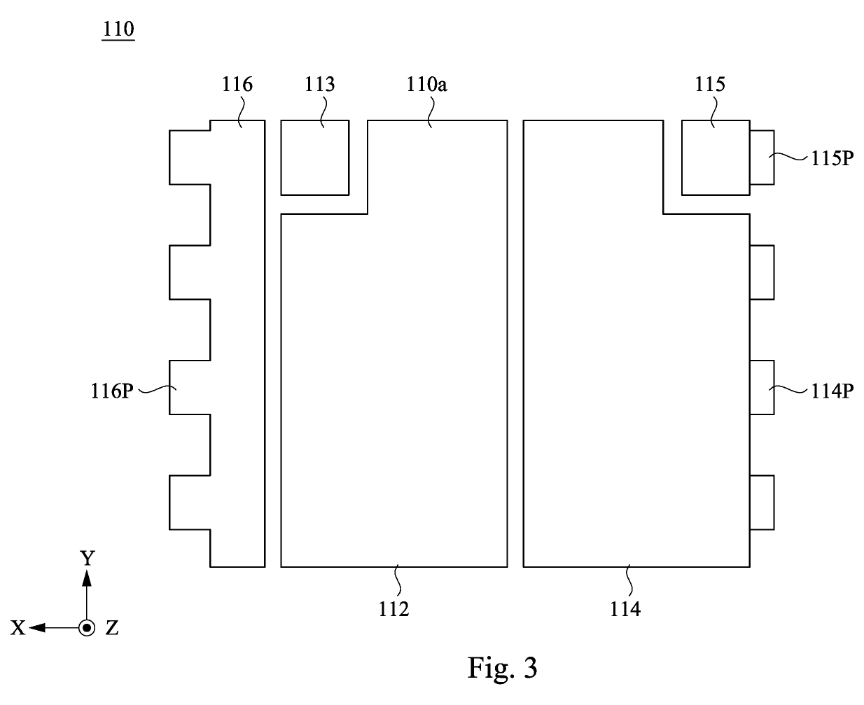

Reference is made to FIG. 3. FIG. 3 is a top view of a conductive part 110 in accordance with an embodiment of the present disclosure. As shown in FIG. 3, in this embodiment, the conductive part 110 has a top surface 110a. It should be noted that the top surface 110a of the conductive part 110 corresponds to the upper surfaces of the first source connecting part 112, the first gate connecting part 113, the second source connecting part 114, the second gate connecting part 115, and the drain connecting part 116. As shown in FIG. 3, in this embodiment, the conductive part 110 further includes a source pin 114P, a gate pin 115P, and a drain pin 116P. The source pin 114P is connected to the second source connecting part 114. The gate pin 115P is connected to the second gate connecting part 115. The drain pin 116P is connected to the drain connecting part 116. In some embodiments, the source pin 114P and the gate pin 115P are located on one end of the entire conductive part 110, and the drain pin 116P is located on the other end of the entire conductive part 110. As shown in FIG. 3, in this embodiment, the first gate connecting part 113 is separated from the first source connecting part 112. The second source connecting part 114 is located on a side of the first source connecting part 112. The second source connecting part 114 is adjacent to and separated from the first source connecting part 112. The second gate connecting part 115 is separated from the second source connecting part 114. The drain connecting part 116 is adjacent to and located on the other side of the first source connecting part 112.

Reference is again made to FIG. 3. As shown in FIG. 3, in this embodiment, the combination of the first source connecting part 112 and the first gate connecting part 113 has a substantially rectangular outline. The combination of the second source connecting part 114 and the second gate connecting part 115 also has a substantially rectangular outline. In some embodiments, the first gate connecting part 113 is surrounded on one side by the drain connecting part 116 and on two sides by the first source connecting part 112. In some embodiments, the first gate connecting part 113 is located between the first source connecting part 112 and the drain connecting part 116. In some embodiments, the first gate connecting part 113 is located at an edge of the conductive part 110. The second gate connecting part 115 is surrounded on two sides by the second source connecting part 114. In some embodiments, the second gate connecting part 115 is located at an edge of the conductive part 110. In some embodiments, the second gate connecting part 115 is located at a corner of the conductive part 110. As shown in FIG. 3, the second source connecting part 114 and the second gate connecting part 115 are located on a side of the first source connecting part 112, and the drain connecting part 116 is located on the other side of the first source connecting part 112. In other words, the drain connecting part 116 is separated from the second source connecting part 114 by the first source connecting part 112.

As shown in FIG. 3, in some embodiments, the first source connecting part 112, the second source connecting part 114, and the drain connecting part 116 are arranged along a direction (e.g., the X-direction).

In some embodiments, the conductive part 110 may include a plurality of source pins 114P, a plurality of gate pins 115P, and a plurality of drain pins 116P. It should be noted that although FIG. 3 depicts three source pins 114P, one gate pin 115P, and four drain pins 116P, the actual quantities of source pins 114P, gate pins 115P, and drain pins 116P may be any possible number. For example, the number of source pins 114P, gate pins 115P, and drain pins 116P may be singular or plural, and may differ from the quantities illustrated in FIG. 3.

In some embodiments, the plurality of source pins 114P and gate pins 115P are arranged along a direction (e.g., the Y-direction), and the plurality of drain pins 116P are also arranged along a direction (e.g., the Y-direction).

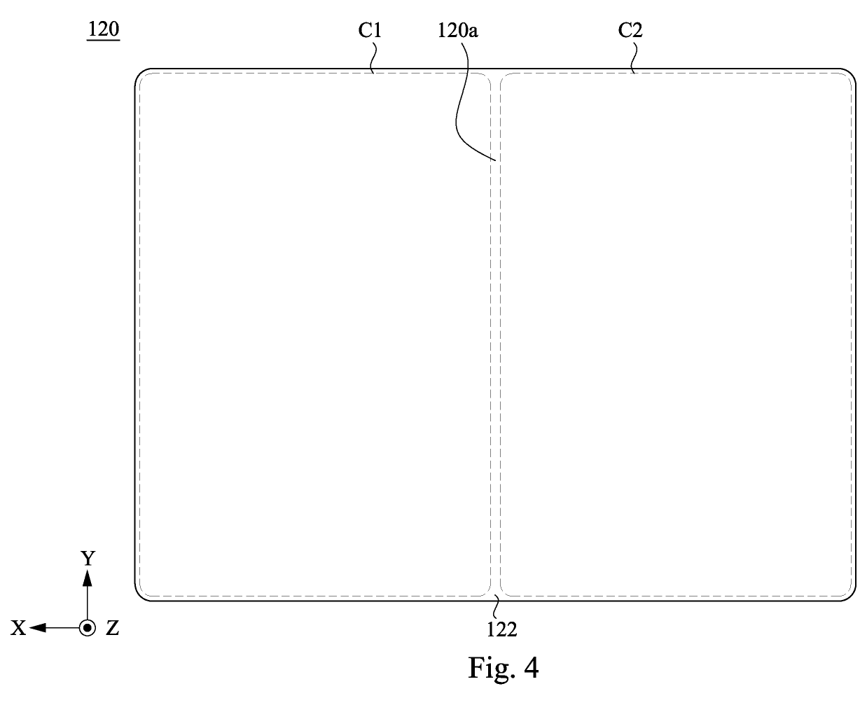

Reference is made to FIG. 4. FIG. 4 is a top view of a chip 120 in accordance with an embodiment of the present disclosure. As shown in FIG. 4, in this embodiment, the chip 120 includes a first subchip C1 and a second subchip C2. It should be noted that the outlines of the first subchip C1 and the second subchip C2 are shown in dashed lines, indicating that the first subchip C1 and the second subchip C2 are located on the back side of the chip 120. Therefore, from the viewing perspective of FIG. 4, the first subchip C1 and the second subchip C2 are actually not visible. As shown in FIG. 4, in this embodiment, the top plate 122 of the chip 120 is plate-shaped. Specifically, the top surface 120a of the chip 120 is a flat surface. Details regarding the first subchip C1 and the second subchip C2 will be described below.

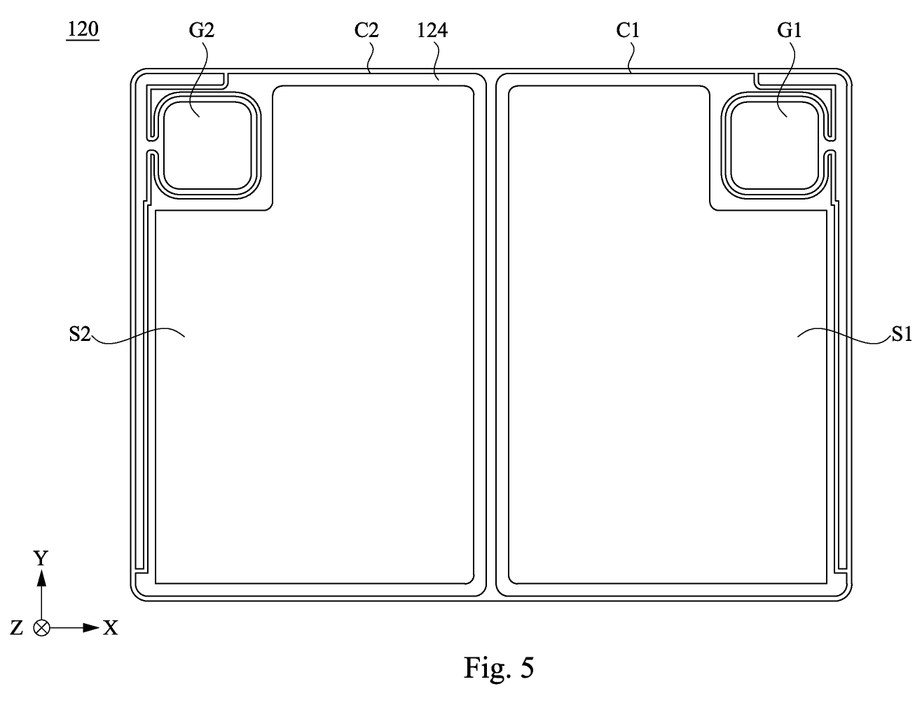

Reference is made to FIG. 5. FIG. 5 is a bottom view of the chip 120 in accordance with an embodiment of the present disclosure. As shown in FIG. 5, in this embodiment, the first subchip C1 is disposed on the bottom surface 120b of the chip 120. The first subchip C1 and the second subchip C2 form the bottom plate 124 of the chip 120. The first subchip C1 includes a first source electrode S1 and a first gate electrode G1. The first gate electrode G1 is connected to the first source electrode S1. The second subchip C2 is disposed on the bottom surface 120b of the chip 120 and is separated from the first subchip C1. The second subchip C2 includes a second source electrode S2 and a second gate electrode G2. The second gate electrode G2 is connected to the second source electrode S2. As shown in FIG. 5, the combination of the first source electrode S1 and the first gate electrode G1 has a substantially rectangular outline. The combination of the second source electrode S2 and the second gate electrode G2 also has a substantially rectangular outline. In some embodiments, the first gate electrode G1 is surrounded on two sides by the first source electrode S1. In some embodiments, the first gate electrode G1 is located at a corner of the conductive part 110. The second gate electrode G2 is surrounded on two sides by the second source electrode S2. In some embodiments, the second gate electrode G2 is located at a corner of the conductive part 110. In some embodiments, the combination of the first source electrode S1 and the first gate electrode G1 is symmetrical with the combination of the second source electrode S2 and the second gate electrode G2.

Reference is made to FIG. 2 and FIG. 5. As shown in FIG. 2 and FIG. 5, in this embodiment, the first source electrode S1 corresponds to the first source connecting part 112, the first gate electrode G1 corresponds to the first gate connecting part 113, the second source electrode S2 corresponds to the second source connecting part 114, and the second gate electrode G2 corresponds to the second gate connecting part 115. Specifically, the first source electrode S1 is connected to the first source connecting part 112, the first gate electrode G1 is connected to the first gate connecting part 113, the second source electrode S2 is connected to the second source connecting part 114, and the second gate electrode G2 is connected to the second gate connecting part 115.

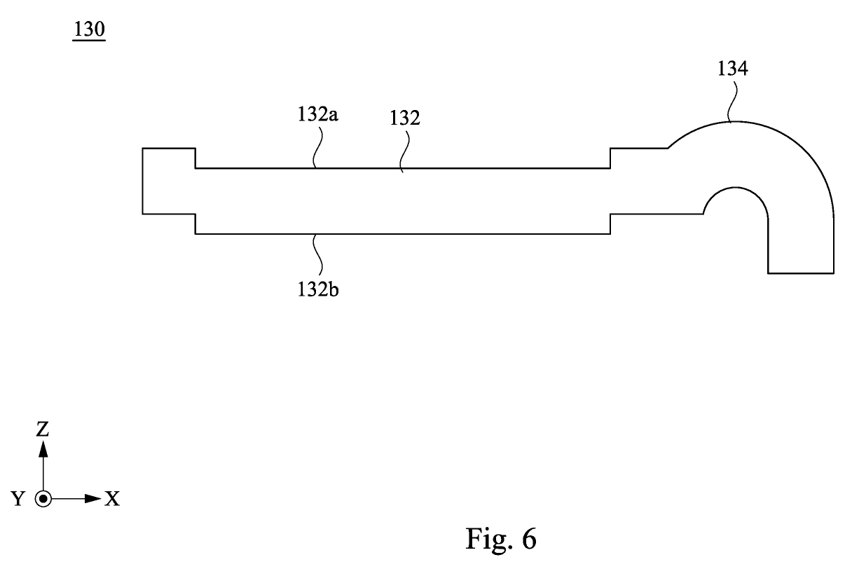

Reference is made to FIG. 6. FIG. 6 is a side view of a copper clip 130 in accordance with an embodiment of the present disclosure. As shown in FIG. 6, in this embodiment, the copper clip 130 includes a horizontal extending portion 132 and a bending portion 134. The horizontal extending portion 132 has a top surface 132a and a bottom surface 132b. The bending portion 134 extends from the horizontal extending portion 132. Specifically, the bending portion 134 extends from one end of the horizontal extending portion 132. In some embodiments, the horizontal extending portion 132 extends along a direction (e.g., the X-direction). The bending portion 134 is arc-shaped. In some embodiments, a portion of the bending portion 134 close to the horizontal extending portion 132 extends in parallel with the horizontal extending portion 132, and a portion of the bending portion 134 away from the horizontal extending portion 132 bends downward. In a usage scenario, the top plate 122 of the chip 120 is electrically connected to the drain connecting part 116 by the copper clip 130.

In some embodiments, the top plate 122 of the chip 120 is configured as a drain electrode.

Reference is made again to FIG. 2 and FIG. 6. As shown in FIG. 2 and FIG. 6, in this embodiment, the horizontal extending portion 132 is disposed on the chip 120. Specifically, the horizontal extending portion 132 is disposed on the top plate 122 of the chip 120. The horizontal extending portion 132 is connected to the top plate 122 of the chip 120, and the bending portion 134 is connected to the drain connecting part 116 of the conductive part 110. In some embodiments, the bottom surface 132b of the horizontal extending portion 132 is connected to the top surface 120a of the chip 120, and an end of the bending portion 134 away from the horizontal extending portion 132 is connected to the drain connecting part 116 of the conductive part 110.

From the above detailed description of the specific embodiments of the present disclosure, it can be clearly seen that in the chip package structure of the present disclosure, since the source electrodes and gate electrodes disposed on the bottom plate of the chip are respectively in contact with the source connecting parts and gate connecting parts of the conductive part, the manufacturer does not need to devote effort to alignment between the chip and the conductive part, thereby achieving an effect of ease of assembly. In the chip package structure of the present disclosure, since the top plate of the chip is in contact with the copper clip, and the bending portion of the copper clip is connected to the drain connecting part, wire bonding is not additionally required, thereby simplifying the structural design. Accordingly, the chip package structure of the present disclosure can effectively reduce manufacturing complexity and address the issue in traditional chip scale packaging in which defective components cannot be manually replaced.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A chip package structure, comprising:
a conductive part, comprising:
a first source connecting part;
a first gate connecting part separated from the first source connecting part;
a second source connecting part located on a side of the first source connecting part;
a second gate connecting part separated from the second source connecting part; and
a drain connecting part adjacent to the first source connecting part;
a chip disposed on the conductive part, the chip comprising:
a bottom plate in contact with the conductive part; and
a top plate connected to the bottom plate;
a copper clip disposed on the chip and connected to the top plate of the chip; and
a packaging material covering the conductive part, the chip, and the copper clip,
wherein the top plate of the chip is electrically connected to the drain connecting part by the copper clip, and the bottom plate of the chip is connected to the first source connecting part, the first gate connecting part, the second source connecting part, and the second gate connecting part.

2. The chip package structure of claim 1, wherein the conductive part further comprises:
a source pin connected to the second source connecting part;
a gate pin connected to the second gate connecting part; and
a drain pin connected to the drain connecting part.

3. The chip package structure of claim 1, wherein the second source connecting part and the second gate connecting part are located on the side of the first source connecting part, and the drain connecting part is located on the other side of the first source connecting part.

4. The chip package structure of claim 1, wherein the first gate connecting part is located between the first source connecting part and the drain connecting part.

5. The chip package structure of claim 1, wherein the drain connecting part is separated from the second source connecting part by the first source connecting part.

6. The chip package structure of claim 1, wherein the bottom plate of the chip comprises:
a first subchip disposed on a bottom surface of the chip, the first subchip comprising a first source electrode and a first gate electrode electrically connected to the first source electrode; and
a second subchip disposed on the bottom surface of the chip and separated from the first subchip, the second subchip comprising a second source electrode and a second gate electrode electrically connected to the second source electrode.

7. The chip package structure of claim 6, wherein the first source electrode is connected to the first source connecting part, the first gate electrode is connected to the first gate connecting part, the second source electrode is connected to the second source connecting part, and the second gate electrode is connected to the second gate connecting part.

8. The chip package structure of claim 1, wherein the copper clip comprises:
a horizontal extending portion disposed on the chip; and
a bending portion extending from an end of the horizontal extending portion.

9. The chip package structure of claim 8, wherein the horizontal extending portion is connected to the top plate of the chip, and the bending portion is connected to the drain connecting part of the conductive part.

10. The chip package structure of claim 8, wherein a bottom surface of the horizontal extending portion is connected to a top surface of the chip.

11. A chip package structure, comprising:
a conductive part, comprising:
a first source connecting part;
a first gate connecting part separated from the first source connecting part;
a second source connecting part located on a side of the first source connecting part;
a second gate connecting part separated from the second source connecting part; and
a drain connecting part adjacent to the first source connecting part;
a chip disposed on the conductive part, the chip comprising:
a bottom plate in contact with the conductive part; and
a top plate connected to the bottom plate; and
a copper clip disposed on the chip and connected to the top plate of the chip and the drain connecting part,
wherein the top plate of the chip is electrically connected to the drain connecting part by the copper clip, and the bottom plate of the chip is connected to the first source connecting part, the first gate connecting part, the second source connecting part, and the second gate connecting part.

12. The chip package structure of claim 11, wherein the conductive part further comprises:
a source pin connected to the second source connecting part;
a gate pin connected to the second gate connecting part; and
a drain pin connected to the drain connecting part.

13. The chip package structure of claim 11, wherein the second source connecting part and the second gate connecting part are located on the side of the first source connecting part, and the drain connecting part is located on the other side of the first source connecting part.

14. The chip package structure of claim 11, wherein the first gate connecting part is located between the first source connecting part and the drain connecting part.

15. The chip package structure of claim 11, wherein the drain connecting part is separated from the second source connecting part by the first source connecting part.

16. The chip package structure of claim 11, wherein the bottom plate of the chip comprises:
a first subchip disposed on a bottom surface of the chip, the first subchip comprising a first source electrode and a first gate electrode electrically connected to the first source electrode; and
a second subchip disposed on the bottom surface of the chip and separated from the first subchip, the second subchip comprising a second source electrode and a second gate electrode electrically connected to the second source electrode.

17. The chip package structure of claim 16, wherein the first source electrode is connected to the first source connecting part, the first gate electrode is connected to the first gate connecting part, the second source electrode is connected to the second source connecting part, and the second gate electrode is connected to the second gate connecting part.

18. The chip package structure of claim 11, wherein the copper clip comprises:
a horizontal extending portion disposed on the chip; and
a bending portion extending from an end of the horizontal extending portion.

19. The chip package structure of claim 18, wherein the horizontal extending portion is connected to the top plate of the chip, and the bending portion is connected to the drain connecting part of the conductive part.

20. The chip package structure of claim 18, wherein a bottom surface of the horizontal extending portion is connected to a top surface of the chip.
